(19) United States
(12) Patent Application Publication
(10) Pub. No.: US 2023/0011104 A1
(43) Pub. Date: Jan. 12, 2023

(54) HEAT DISSIPATION STRUCTURE FOR REACTOR AND INVERTER

(71) Applicant: Sungrow Power Supply Co., Ltd., Hefei (CN)

(72) Inventors: Jie Zhou, Hefei (CN); Renbin Yu, Hefei (CN)

(73) Assignee: Sungrow Power Supply Co., Ltd., Hefei (CN)

(21) Appl. No.: 17/852,214

(22) Filed: Jun. 28, 2022

(30) Foreign Application Priority Data
Jul. 9, 2021 (CN) 202121581781.X

(51) Int. Cl. H05K 7/20

(52) U.S. Cl. CPC H05K 7/20927; H05K 7/20263; H05K 7/20145; H05K 7/20909

(57) ABSTRACT

A heat dissipation structure for the reactor includes a housing, a reactor body, and one or more heat dissipation pipes. Each of the one or more heat dissipation pipes is disposed in a cavity of the housing and is connected to the housing in a leak-tight manner, a closed cavity is formed between the one or more heat dissipation pipes and the housing, and the reactor body is disposed in the closed cavity. The above heat dissipation structure for the reactor allows to improve the heat dissipation effect of the reactor under the premise that protection requirements are met. The current carrying density of the coil of the reactor body can be increased and the diameter of copper wires can be reduced under the same conditions, thereby reducing the usage of copper and effectively reducing the cost and weight.

### CROSS REFERENCE TO RELATED APPLICATIONS

This application claims the priorities to Chinese patent application No. 202121581781.X, titled “HEAT DISSIPATION STRUCTURE FOR REACTOR AND INVERTER”, filed with the China National Intellectual Property Administration Jul. 9, 2021, the entire disclosure of which is hereby incorporated by reference.

### FIELD

The present application relates to the field of inverters, in particular to a heat dissipation structure for a reactor and an inverter.

### BACKGROUND

A manufacturing process for a reactor of a string inverter is as follows. A housing with teeth is firstly die-casted, then a reactor body including a magnetic core and a coil is placed into the housing, and potting sealant is filled into the housing to ensure the housing to be leak-tight, so as to achieve high protection effects such as waterproof and dustproof.

The above-described reactor mainly utilizes a cooling method in which the heat radiated by the reactor body is dissipated to the outside by providing a separate cooling fan or using a wind for cooling a power module. The heat dissipation effect of the reactor body is poor due to the reactor body being wrapped by the potting sealant and the housing, and the current carrying density of the coil is relatively low under the same conditions.

In addition, since the reactor body needs to be wrapped by the housing and the potting sealant, the entire reactor has a relatively large size and a relatively heavy weight.

In summary, how to improve the heat dissipation effect of the reactor on the premise that protection requirements are met is an urgent problem to be solved by those skilled in the art.

### SUMMARY

In view of this, an object of the present application is to provide a heat dissipation structure for a reactor, which can improve the heat dissipation effect of the reactor on the premise that protection requirements are met. Another object of the present application is to provide an inverter including the above-described heat dissipation structure for the reactor.

In order to achieve the above objects, the following technical solutions are provided according to the present application.

A heat dissipation structure for a reactor includes: a housing, a reactor body, and one or more heat dissipation pipes, the one or more heat dissipation pipes are disposed in a cavity of the housing and is connected to the housing in a leak-tight manner, a closed cavity is formed between the one or more heat dissipation pipes and the housing, and the reactor body is disposed in the closed cavity.

Optionally, each of pipe openings at both ends of the one or more heat dissipation pipes extends beyond the housing, and the one or more heat dissipation pipes are used for cooling medium to flow through.

Optionally, the heat dissipation structure for the reactor further includes: one or more heat dissipation fins disposed in the closed cavity, which are disposed at at least one of the one or more heat dissipation pipes.

Optionally, at least one of the one or more heat dissipation fins is disposed at only one of the one or more heat dissipation pipes.

Optionally, at least one of the one or more heat dissipation fins is disposed at at least two of the one or more heat dissipation pipes.

Optionally, at least two heat dissipation fins are disposed at the at least one of the one or more heat dissipation pipes, and are sequentially distributed along an axial direction of the at least one heat dissipation pipe or sequentially distributed along a circumferential direction of the at least one heat dissipation pipe.

Optionally, the heat dissipation structure for the reactor further includes an outer fan and an air duct disposed outside the housing, where an air outlet of the outer fan and an inlet of the one or more heat dissipation pipes are communicated through the air duct, or an air inlet of the outer fan and an outlet of the one or more heat dissipation pipes are communicated through the air duct.

Optionally, one end of the air duct is connected to the outer fan in a leak-tight manner, the other end of the air duct is connected to the housing in a leak-tight manner, and the air duct is covered at the periphery of the one or more heat dissipation pipes.

Optionally, the heat dissipation structure for the reactor further includes at least one inner fan disposed in the closed cavity.

Optionally, a number of the at least one inner fan is two, and two inner fans are disposed at two ends of the housing respectively, one of the two inner fans being disposed on one side of the reactor body and the other inner fan being disposed on the other side of the reactor body.

Optionally, the one or more heat dissipation pipes are distributed in rows, and the heat dissipation pipes in any two rows are sequentially distributed along an airflow direction, where in the heat dissipation pipes in adjacent rows, the heat dissipation pipes in one row and the heat dissipation pipes in the other row are alternatively arranged.

Optionally, the one or more heat dissipation fins are provided in groups, and any two groups of the heat dissipation fins are sequentially distributed in an airflow direction, where in adjacent two groups of the heat dissipation fins, the heat dissipation fins in one group and the heat dissipation fins in the other group are alternatively arranged.

Optionally, the housing is in a shape of a rectangular solid, and an axial direction of the one or more heat dissipation pipes is parallel to a width direction of the housing.

Optionally, the one or more heat dissipation pipes are fixedly connected with the housing.

Optionally, the one or more heat dissipation pipes are welded to the housing or fixed to the housing through a flange.

Optionally, potting sealant is provided in the housing.

In the heat dissipation structure for the reactor according to the present application, heat exchange occurs between the air in the closed cavity and the heat dissipation pipes, and the heat in the heat dissipation pipes is dissipated through the housing, thereby realizing the heat dissipation of the reactor body, and the heat in the closed cavity is directly dissipated to the outside through the heat dissipation pipes and the housing, which improves the heat dissipation effect of the reactor in comparison with the conventional technology. In addition, the heat dissipation pipes are connected to the housing in a leak-tight manner, the closed cavity is formed by the heat dissipation pipes and the housing, and the reactor body is disposed in the closed cavity. Thus the protection requirements of the reactor, for example the high protection requirements of being waterproof and dustproof, can be met. Therefore, the above-described heat dissipation structure for the reactor allows to improve the heat dissipation effect of the reactor under the premise that the protection requirements are met.

In addition, the heat dissipation structure for the reactor according to the present application allows to improve the heat dissipation effect of the reactor, the current carrying density of the coil of the reactor body can be increased and the diameter of copper wires can be reduced under the same conditions, thereby reducing the usage of copper and effectively reducing the cost and weight.

In addition, in the heat dissipation structure for the reactor according to the present application, the closed cavity is formed between the heat dissipation pipes and the housing, and potting sealant may not be provided. The size, weight, and cost of the entire reactor are reduced in comparison with the conventional technology.

Based on the heat dissipation structure for the reactor provided above, the present application further provides an inverter including a heat dissipation structure for a reactor, and the heat dissipation structure for the reactor is any one of the heat dissipation structures for the reactor described above.

Optionally, the housing is fixed to one side of an inverter main body housing.

### BRIEF DESCRIPTION OF THE DRAWINGS

For more clearly illustrating embodiments of the present application or the technical solutions in the conventional technology, drawings referred to for describing the embodiments or the conventional technology will be briefly described hereinafter. Apparently, the drawings in the following description are only examples of the present application, and for those skilled in the art, other drawings may be obtained based on the drawings provided without any creative efforts.

FIG. 1 is a schematic diagram showing the structure of a heat dissipation structure for a reactor according to an embodiment of the present application;

FIG. 2 is a front sectional view of the structure shown in FIG. 1;

FIG. 3 is a top sectional view of the structure shown in FIG. 1;

FIG. 4 is a side sectional view of the structure shown in FIG. 1;

FIG. 5 is another schematic diagram showing the structure of a heat dissipation structure for a reactor according to an embodiment of the present application; and

FIG. 6 is an installation schematic diagram of a heat dissipation structure for a reactor according to an embodiment of the present application.

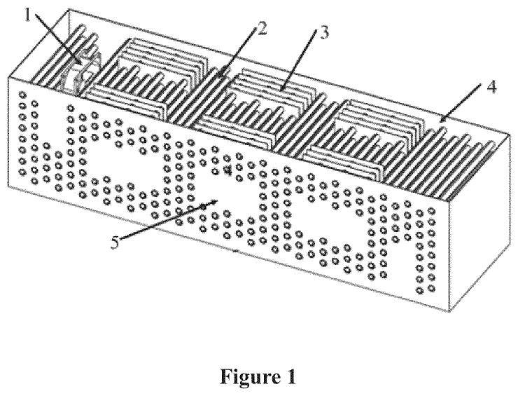

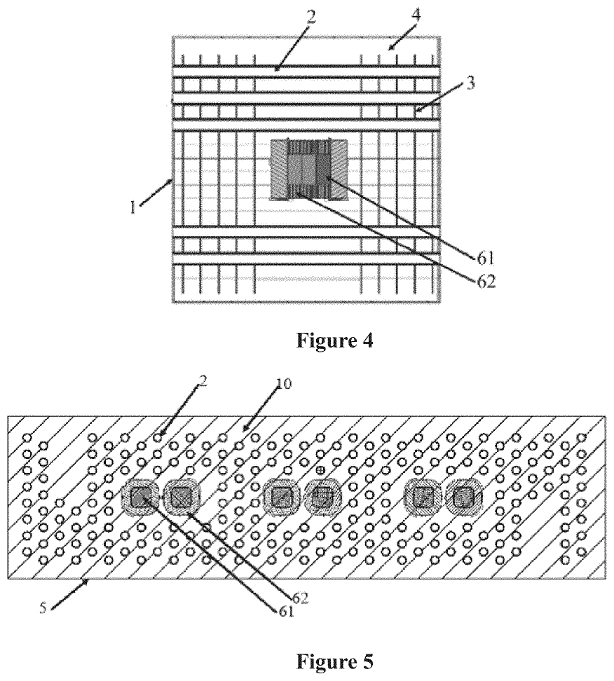

In FIGS. 1-6, an inner fan 1, a heat dissipation pipe 2, a heat dissipation fin 3, a closed cavity 4, a housing 5, a reactor body 6, a magnetic core 61, a coil 62, an air duct 7, an outer fan 8, an inverter main body housing 9, and potting sealant 10 are illustrated.

### DETAILED DESCRIPTION

The technical solutions according to the embodiments of the present application will be described clearly and completely hereafter in conjunction with the drawings in the embodiments of the present application. It is apparent that the described embodiments are only a part of the embodiments according to the present application, rather than all of the embodiments. Based on the embodiments in the present application, all of other embodiments, made by those skilled in the art without any creative efforts, fall into the scope of protection of the present application.

As shown in FIGS. 1-6, the heat dissipation structure for the reactor according to an embodiment of the present application includes: a housing 5, a reactor body 6, and one or more heat dissipation pipes 2. The one or more heat dissipation pipes 2 are disposed in a cavity of the housing 5 and are connected to the housing 5 in a leak-tight manner. A closed cavity 4 is formed between the one or more heat dissipation pipes 2 and the housing 5, and the reactor body 6 is disposed in the closed cavity 4.

It should be noted that the above-described reactor body 6 includes a magnetic core 61 and a coil 62 wound around the magnetic core 61. In FIG. 1, the housing 5 is only partially shown, and a top cover of the housing 5 is not shown.

In the heat dissipation structure for the reactor according to above embodiments, heat exchange occurs between the air in the closed cavity and the one or more heat dissipation pipes 2, and the heat in the one or more heat dissipation pipes 2 is dissipated through the housing 5, thereby realizing the heat dissipation of the reactor body 6. The heat in the closed cavity is directly dissipated to the outside through the one or more heat dissipation pipes 2 and the housing 5, which improves the heat dissipation effect of the reactor in comparison with the conventional technology. In addition, the one or more heat dissipation pipes 2 are connected to the housing 5 in a leak-tight manner, a closed cavity is formed by the one or more heat dissipation pipes 2 and the housing 5, and the reactor body 6 is disposed in the closed cavity. Thus the protection requirements of the reactor, for example the high protection requirements of waterproof and dustproof, can be met. Therefore, the above-described heat dissipation structure for the reactor allows to improve the heat dissipation effect of the reactor under the premise that the protection requirements are met.

In addition, the heat dissipation structure for the reactor according to the above embodiments allows to improve the heat dissipation effect of the reactor. The current carrying density of the coil 62 of the reactor body 6 can be increased and the diameter of copper wires can be reduced under the same conditions, thereby reducing the usage of copper and effectively reducing the cost and weight.

In addition, in the heat dissipation structure for the reactor according to the above embodiments, the closed cavity 4 is formed by the one or more heat dissipation pipes 2 and the housing 5, and potting sealant may not be provided. The size, weight, and cost of the entire reactor are reduced in comparison with the conventional technology.

In order to further improve the heat dissipation effect, each of pipe openings at both ends of the above-described one or more heat dissipation pipes 2 extends beyond the housing 5, and the heat dissipation pipes 2 are used for cooling medium to flow through.

It can be understood that each of the pipe openings at both ends of the above-described one or more heat dissipation pipes 2 extends beyond the housing 5 to ensure the inflow and outflow of the cooling medium. Specifically, the pipe openings of the heat-dissipating pipes 2 can be aligned with the outer wall of the housing 5, protrude from the outer wall of the housing 5, or be embedded in the outer wall of the housing 5. In the actual application process, selection can be made according to actual needs, which is not limited in the embodiments. The type of the above cooling medium can be selected according to actual needs, which is not limited in the embodiments.

In the heat dissipation structure for the reactor according to the above embodiments, the cooling medium, when flowing through the one or more heat dissipation pipes 2, exchanges heat with the air in the closed cavity 4, that is, the cooling medium, when flowing through the one or more heat dissipation pipes 2, takes away the heat in the closed cavity 4. Therefore, the heat dissipation of the reactor body 6 is realized, and the heat dissipation effect of the reactor is further improved.

In order to ensure that each of the pipe openings at both ends of the one or more heat dissipation pipes 2 extends beyond the housing 5, the housing 5 is provided with through holes into which the one or more heat dissipation pipes 2 are inserted. At the through holes, the outer wall of the heat dissipation pipes 2 and the housing 5 are connected in a leak-tight manner.

The number of the above-described heat dissipation pipes 2 can be selected according to actual needs. In order to improve the heat dissipation effect, the number of the heat dissipation pipe 2 can be at least two. The arrangement of the at least two heat dissipation pipes 2 is selected according to actual needs. For example, the at least two heat dissipation pipes 2 are arranged in rows or columns, which is not limited in the embodiments.

Each of the above-described heat dissipation pipes 2 can be of a straight pipe, a curved pipe or a pipe with other shapes, which can be selected according to actual needs. In order to shorten the cooling path of the cooling medium, the above-described heat dissipation pipes 2 can be of a straight pipe.

In order to improve the heat dissipation effect, the above-described heat dissipation structure for the reactor further includes one or more heat dissipation fins 3 disposed in the closed cavity 4, which are disposed at at least one of the one or more heat dissipation pipes 2.

The shape of the above-described heat dissipation fins 3 can be selected according to actual needs, for example, each of the above-described heat dissipation fins 3 are of a shape of a sheet or a needle, et al.

The arrangement of the heat dissipation fins 3 can be selected according to actual needs. For example, the one or more heat dissipation fins 3 can be disposed at only one heat dissipation pipe 2. Alternatively, the one or more heat dissipation fins 3 are disposed at the at least two heat dissipation pipes 2.

Specifically, at least two heat dissipation fins 3 are disposed at the at least one heat dissipation pipe 2, and are sequentially arranged along an axial direction of the at least one heat dissipation pipe 2. Alternatively, the heat dissipation fins 3 disposed at the at least one heat dissipation pipe 2 can be arranged along a circumferential direction of the at least one heat dissipation pipe 2.

In the actual application process, the above-described heat dissipation fins 3 disposed at the heat dissipation pipes 2 can also be arranged in other ways, which is not limited to the above embodiments.

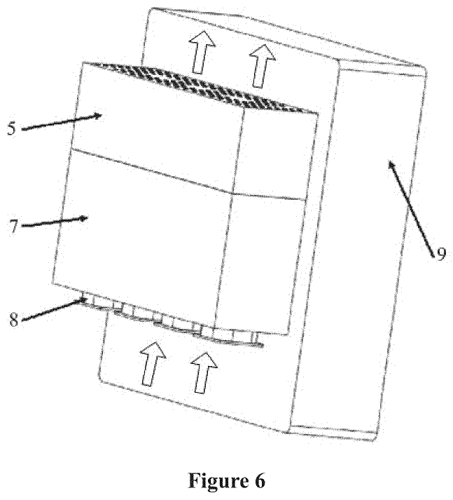

In the actual application process, the cooling medium flowing through the heat dissipation pipes 2 can be water, air or refrigerant, etc., which can be selected according to actual needs. For the convenience of application, the above-described cooling medium can be air. In order to facilitate the cooling medium flowing through the above-described heat dissipation pipes 2, as shown in FIG. 6, the above-described heat dissipation structure for the reactor further includes an outer fan 8 and an air duct 7 disposed outside the housing 5, and an air outlet of the outer fan 8 and an inlet of the heat dissipation pipes 2 are communicated through the air duct 7, or an air inlet of the outer fan 8 and an outlet of the heat dissipation pipes 2 are communicated through the air duct 7.

It can be understood that the pipe opening at one end of the above-described heat dissipation pipes 2 is an inlet of the heat dissipation pipes 2, and the pipe opening at the other end of the heat dissipation pipes 2 is an outlet of the heat dissipation pipes 2. The hollow arrows in FIG. 6 indicate the airflow direction.

In order to facilitate the arrangement of the air duct 7, one end of the air duct 7 is connected to the outer fan 8 in a leak-tight manner, the other end of the air duct 7 is connected to the housing 5 in a leak-tight manner, and the air duct 7 covers the periphery of the inlets of all of the heat dissipation pipes 2. In this case, the number of the air duct 7 is one.

Specifically, if the air outlet of the outer fan 8 and the inlet of the heat dissipation pipes 2 are communicated through the air duct 7, then one end of the air duct 7 is connected to the air outlet of the outer fan 8 in a leak-tight manner, and the other end of the above-described air duct 7 covers the periphery of the inlets of all of the heat dissipation pipes 2. If the air inlet of the outer fan 8 and the outlet of the heat dissipation pipes 2 are communicated through the air duct 7, one end of the above-described air duct 7 is connected with the air inlet of the outer fan 8 in a leak-tight manner, and the other end of the air duct 7 covers the periphery of the outlet of all of the heat dissipation pipes 2.

In the actual application process, the above-described air duct 7 may also be selected to be other structures, and the number of the above-described air duct 7 may be two or more than two, which is not limited to the above-described embodiments.

In order to further improve the heat dissipation effect, the above-described heat dissipation structure for the reactor further includes at least one inner fan 1 disposed in the closed cavity 4.

In the above-described structure, the airflow is formed in the closed cavity 4, and the heat dissipation effect of the air and the heat dissipation pipes 2 is enhanced by providing the inner fan 1. Moreover, the turbulence to the airflow is realized, and the heat dissipation effect is also improved under the effects of the heat dissipation pipes 2.

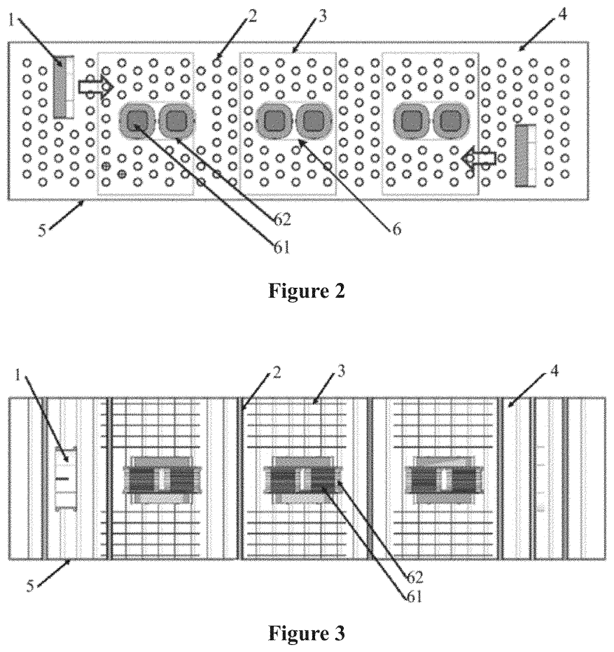

The number of the inner fan 1 can be selected according to actual needs, which is not limited in this embodiment. In order to facilitate the airflow flowing in the closed cavity 4, the number of the above-described inner fan 1 can be two and two inner fans 1 are disposed at two ends of the housing 5 respectively. One inner fan 1 of the two inner fans 1 is disposed on one side of the reactor body 6, and the other inner fan 1 is disposed on the other side of reactor body 6, as shown in FIG. 2. It can be understood that the above-described inner fan 1 is in the circulating airflow. The hollow arrows in FIG. 2 indicate the airflow direction.

In the actual application process, the number of the above-described inner fan 1 can also be three or more than three, which is not limited to the above-described embodiments.

In the above-described structure, if the heat dissipation fins 3 are provided in the closed cavity 4, a gap, used for the airflow in the closed cavity 4 to pass through, can be provided between two adjacent heat dissipation fins 3.

In order to improve the turbulence effect of the heat dissipation pipes 2, the above-described heat dissipation pipes 2 can be arranged in a row, and the heat dissipation pipes 2 in any two rows are sequentially arranged along an airflow direction, and in the heat dissipation pipes 2 in adjacent rows, the heat dissipation pipes 2 in one row and the heat dissipation pipes 2 in the other row are alternatively arranged. It can be understood that the airflow direction is the flow direction of the airflow generated by the inner fan 1 in the closed cavity. The above-described the heat dissipation pipes 2 in one row and the heat dissipation pipes 2 in the other row that are alternatively arranged can be understood as that the projections of the heat dissipation pipes 2 in one row and the heat dissipation pipes 2 in the other row along the airflow direction do not overlap or only partially overlap.

Specifically, as shown in FIG. 2, each row of heat dissipation pipes 2 includes at least two heat dissipation pipes 2, which are sequentially distributed in the height direction of the housing 5. The adjacent two rows of heat dissipation pipes 2 are sequentially distributed along the length direction of the housing 5. In two adjacent rows of heat dissipation pipes 2, the heat dissipation pipes 2 in one row and the heat dissipation pipes 2 in the other row are alternatively arranged, that is, the projections of the heat dissipation pipes 2 in one row and the heat dissipation pipes 2 in the other row along the length direction of the housing 5 do not overlap or only partially overlap.

In each row of the heat dissipation pipes 2, any two heat dissipation pipes 2 can be sequentially arranged in a direction perpendicular to the airflow direction or in other directions, as long as it is ensured that the airflow can pass between the two adjacent heat dissipation pipes 2.

In order to improve the turbulence effect of the heat dissipation fins 3, the heat dissipation fins 3 can be provided in groups, and any two groups of heat dissipation fins 3 are sequentially distributed in the airflow direction. In the adjacent two groups of heat dissipation fins 3, the heat dissipation fins 3 in a group and in the other group are alternatively arranged. It can be understand that the heat dissipation fins 3 in a group and in the other group have non-overlapped or partially-overlapped projections in the airflow direction. It can be understood that the projections of the heat dissipation fins 3 in one group and the heat dissipation fins 3 in the other group along the airflow direction do not overlap or only partially overlap. The airflow direction is the flow direction of the airflow generated by the inner fan 1 in the closed cavity.

In each group of the heat dissipation fins 3, any two heat dissipation fins 3 may be sequentially arranged in a direction perpendicular to the airflow direction, or may be sequentially arranged in other directions, as long as it is ensured that the airflow can pass between the two adjacent heat dissipation fins 3.

In the actual application process, in order to improve the heat dissipation effect to a largest extent, the above-described heat dissipation structure for the reactor can include an inner fan 1, an outer fan 8 and an air duct 7. The inner fan 1 quickly transfer the heat emitted by the reactor body 6 to the air through turbulence. Then the heat in the air is transferred to the heat dissipation pipes 2 through convection heat exchange, and the outer fan 8 blows the cold air into the heat dissipation pipes 2 and takes away the heat on the heat dissipation pipes 2 and dissipates the heat to the outside, so as to realize the heat dissipation of the reactor body 6.

In the actual application process, the number of the reactor body 6 in the above-described closed cavity 4 may be one, two or more than two, which may be selected according to actual needs. In order to facilitate the arrangement of the reactor body 6 and improve the heat dissipation effect, the above-described heat dissipation pipes 2 are disposed at the periphery of the reactor body 6.

In the above-described heat dissipation structure for the reactor, the shape of the housing 5 can be selected according to actual needs. In order to facilitate the installation of the heat dissipation pipes 2, the above-described housing 5 can be in a shape of a rectangular solid. In order to improve the heat dissipation effect, the axial direction of the heat dissipation pipes 2 can be parallel to the width direction of the housing 5, so that the cooling path of the cooling medium can be shortened as much as possible, thereby improving the heat dissipation effect. Certainly, the axial direction of the heat dissipation pipes 2 can also be parallel to the longitudinal direction or the height direction of the housing 5, which is not limited to the above-described embodiments.

In the actual application process, the above-described housing 5 may also be cylindrical or other shapes, which are not limited in this embodiment.

In the above-described heat dissipation structure for the reactor, the type of the housing 5 can be selected according to actual needs. For example, the above-described housing 5 may be a die-cast housing, which is not limited in this embodiment.

In the above-described heat dissipation structure for the reactor, the heat dissipation pipes 2 are fixedly connected with the housing 5. Specifically, the heat dissipation pipes 2 can be welded to the housing 5, the heat dissipation pipes 2 are fixed to the housing 5 through a flange, or the heat dissipation pipes 2 are bonded to the housing 5. In order to facilitate disassembly and maintenance, the above-described heat dissipation pipes 2 can be detachably and fixedly connected to the housing 5, for example, the heat dissipation pipes 2 are fixed to the housing 5 through a flange. Certainly, the above-described heat dissipation pipes 2 can also be fixedly connected to the housing 5 by other means, which is not limited in this embodiment.

In the above-described heat dissipation structure for the reactor, the housing 5 may be provided with potting sealant 10, as shown in FIG. 5. The housing 5 may also not be provided with the potting sealant 10, as shown in FIGS. 1-4.

In order to improve the heat dissipation effect, the above-described housing 5 can be provided with the potting sealant 10, so that the heat dissipation pipes 2 pass through the potting sealant 10, which reduces the thermal resistance from the heat in the closed cavity 4 to the heat dissipation pipes 2, thereby improving the heat radiation effect. It can be understood that, if the housing 5 is provided with the potting sealant 10, the above-described heat dissipation structure for the reactor does not include the inner fan 1. In this case, the volume is larger, the weight is larger, and the cost is higher in comparison with not disposing the potting sealant 10.

Based on the heat dissipation structure for the reactor according to above-described embodiments, an inverter is further provided according to the embodiment. The inverter includes a heat dissipation structure for a reactor, and the heat dissipation structure for the reactor is the heat dissipation structure for the reactor described in the above embodiments.

Since the heat dissipation structure for the reactor according to above embodiments has the above technical effects, and the above-described inverter includes the above-described heat dissipation structure for the reactor, the above-described inverter also has corresponding technical effects, which will not be repeated herein.

The above-described inverter includes an inverter main body and a heat dissipation structure for a reactor, where the inverter main body has an inverter main body housing 9. In order to facilitate installation, the above-described housing 5 can be fixed to one side of the inverter main body housing 9.

Specifically, the above-described housing 5 is fixed to one side of the inverter main body housing 9 by bolts. If the above-described heat dissipation structure for the reactor includes an air duct 7 and an outer fan 8, the air duct 7 and the outer fan 8 can be fixed to the inverter main body housing 9. Further, the housing 5, the air duct 7 and the outer fan 8 are fixed to the same side of the inverter main body housing 9.

In the above-described inverter, the above-described housing 5 may also be fixed to the inverter main body housing 9 by other means, which are selected according to actual needs and are not limited in this embodiment.

In the practical application process, the above-described heat dissipation structure for the reactor can also be applied to other electronic equipment including a reactor, which is not limited to the above-described inverter.

The above description of the disclosed embodiments enables those skilled in the art to implement or carry out the present application. Various modifications to these embodiments will be readily apparent to those skilled in the art, and the general principles defined herein may be applied to other embodiments without departing from the spirit or scope of the present application. Therefore, the present application is not limited to the embodiments illustrated herein, but should be defined by the widest scope consistent with the principle and novel features disclosed herein.

1. A heat dissipation structure for a reactor, comprising:
a housing;
a reactor body; and
one or more heat dissipation pipes; wherein
the one or more heat dissipation pipes are disposed in a cavity of the housing and are connected to the housing in a leak-tight manner, a closed cavity is formed by the one or more heat dissipation pipes and the housing, and the reactor body is disposed in the closed cavity.

2. The heat dissipation structure for the reactor according to claim 1, wherein each of pipe openings at both ends of the one or more heat dissipation pipes extends beyond the housing, and the one or more heat dissipation pipes are used for cooling medium to flow through.

3. The heat dissipation structure for the reactor according to claim 1, further comprising:
one or more heat dissipation fins disposed in the closed cavity, which are disposed at at least one of the one or more heat dissipation pipes.

4. The heat dissipation structure for the reactor according to claim 3, wherein the at least one of the one or more heat dissipation fins is disposed at only one of the one or more heat dissipation pipes.

5. The heat dissipation structure for the reactor according to claim 3, wherein the at least one of the one or more heat dissipation fins is disposed at at least two of the one or more heat dissipation pipes.

6. The heat dissipation structure for the reactor according to claim 3, wherein at least two heat dissipation fins are disposed at the at least one of the one or more heat dissipation pipes, and are sequentially arranged along an axial direction of the at least one heat dissipation pipe or sequentially arranged along a circumferential direction of the at least one heat dissipation pipe.

7. The heat dissipation structure for the reactor according to claim 1, further comprising:
an outer fan and an air duct disposed outside the housing, wherein an air outlet of the outer fan and an inlet of the one or more heat dissipation pipes are communicated through the air duct, or an air inlet of the outer fan and an outlet of the one or more heat dissipation pipes are communicated through the air duct.

8. The heat dissipation structure for the reactor according to claim 7, wherein one end of the air duct is connected to the outer fan in a leak-tight manner, the other end of the air duct is connected to the housing in a leak-tight manner, and the air duct covers the periphery of the one or more heat dissipation pipes.

9. The heat dissipation structure for the reactor according to claim 1, further comprising:
at least one inner fan disposed in the closed cavity.

10. The heat dissipation structure for the reactor according to claim 9, wherein a number of the at least one inner fan is two, and two inner fans are disposed at two ends of the housing respectively, one of the two inner fans is disposed on one side of the reactor body and the other inner fan is disposed on the other side of the reactor body.

11. The heat dissipation structure for the reactor according to claim 9, wherein the one or more heat dissipation pipes are arranged in rows, and the heat dissipation pipes in any two rows are sequentially arranged along an airflow direction, wherein in the heat dissipation pipes in adjacent rows, the heat dissipation pipes in one row and the heat dissipation pipes in the other row are alternatively arranged.

12. The heat dissipation structure for the reactor according to claim 9, wherein the one or more heat dissipation fins are provided in groups, and any two groups of the heat dissipation fins are sequentially arranged in an airflow direction, wherein in adjacent two groups of the heat dissipation fins, the heat dissipation fins in one group and the heat dissipation fins in the other group are alternatively arranged.

13. The heat dissipation structure for the reactor according to claim 1, wherein the housing is in a shape of a rectangular solid, and an axial direction of the one or more heat dissipation pipes is parallel to a width direction of the housing.

14. The heat dissipation structure for the reactor according to claim 1, wherein the one or more heat dissipation pipes are fixedly connected with the housing.

15. The heat dissipation structure for the reactor according to claim 14, wherein the one or more heat dissipation pipes are welded to the housing or fixed to the housing through a flange.

16. The heat dissipation structure for the reactor according to claim 1, wherein potting sealant is provided in the housing.

17. An inverter comprising a heat dissipation structure for a reactor, wherein the heat dissipation structure for the reactor is the heat dissipation structure for the reactor according to claim 1.

18. The inverter according to claim 17, wherein the housing is fixed to one side of an inverter main body housing.
